(19) United States
(12) Patent Application Publication
(10) Pub. No.: US 2023/0402248 A1
(43) Pub. Date: Dec. 14, 2023

(54) Vacuum Treatment Apparatus and Vacuum Treatment Method

(71) Applicant: Hitachi High-Tech Corporation, Minato-ku, Tokyo (JP)

(72) Inventors: Akito TANOKUCHI, Tokyo (JP); Hiroki TSUBOUCHI, Tokyo (JP); Takao UBUKATA, Tokyo (JP)

(21) Appl. No.: 18/034,929

(22) PCT Filed: Dec. 16, 2020
(86) PCT No.: PCT/JP2020/046967

§ 371 Date: May 2, 2023

(51) Int. Cl. H01J 37/18; H01J 37/28

(52) U.S. Cl. CPC H01J 37/18; H01J 37/28; H01J 2237/1825

(57) ABSTRACT

Provided are a vacuum treatment device and a vacuum treatment method with which it is possible to suppress deterioration of the degree of vacuum in a conveyance destination vacuum chamber when conveying a sample between two vacuum chambers. In this regard, a control device 30 controls conveyance of a wafer 600 from LC 102 to SC 101 via a LC-SC gate valve 510. At this time, the control device stops vacuum evacuation, which is being performed by a TMP 401A for a first duration of time, after having controlled the LC-SC gate valve 510 to close, measures an internal pressure of the LC 102 by using a pressure gauge 103 in a condition in which the vacuum evacuation is stopped, and controls the LC-SC gate valve 510 to open if the measured internal pressure has reached a first reference value.

### TECHNICAL FIELD

The present invention relates to a vacuum treatment apparatus and a vacuum treatment method, in particular to an apparatus for performing treatment on a semiconductor wafer releasing gas.

### BACKGROUND ART

In the device manufacturing line, an apparatus which applied a scanning electron microscope is used to measure a dimension of the fine pattern formed on a semiconductor wafer (hereafter, the wafer) and inspect the defect on the device. For example, a CD-SEM (Critical Dimension-Scanning Electron Microscope) is used for dimension measurement of gates and contact holes of semiconductor devices, and a defect inspection SEM or the like is used for defect inspection.

PTL 1 discloses a charged particle beam apparatus capable of appropriately maintaining the throughput of the apparatus for each sample with different amounts of gas release. The charged particle beam apparatus switches a determination value for completing vacuum evacuation in an exchange chamber between the sample with a large amount of gas release and the sample with a small amount of gas release when conveying the sample from the exchange chamber to a sample chamber.

### CITATION LIST

### Patent Literature

PTL 1: JP2013-182792A

### SUMMARY OF INVENTION

### Technical Problem

An outline of a vacuum treatment apparatus will be described by taking a CD-SEM, which is one of the vacuum treatment apparatuses, as an example. A CD-SEM has a configuration in which a load lock chamber (hereafter referred to as LC) that loads the wafer to be inspected into the apparatus from the outside of the apparatus is connected to a main chamber (hereafter referred to as SC) that irradiates the wafer with an electron beam for inspection. An electron optical system is installed in the SC and irradiates the wafer in the SC with an electron beam.

Under normal use conditions of the apparatus, the pressure of the SC is required to be kept at a high vacuum state to be able to perform measurements by irradiation with the electron beam. On the other hand, the pressure in the LC plays a role of a front chamber when conveying a wafer between the outside of the apparatus and the SC, and thus, fluctuates rapidly from atmospheric pressure to high vacuum each time a wafer is taken in or a wafer that has finished inspection is taken out. For this purpose, the LC and SC are each equipped with a turbomolecular pump (TMP).

In addition, apart from the evacuation by TMP, the LC includes a roughing pump (such as a dry pump) that is responsible for vacuuming from the atmosphere to a low vacuum, and a vent device for returning the inside of the LC to atmospheric pressure using nitrogen (N 2). Regarding the chamber volumes of the LC and the SC, there is a relationship that the LC is small and the SC is large. This is because a small LC volume is desirable due to the need for pressure fluctuations.

Next, the wafer conveyance in the CD-SEM and the accompanying vacuum evacuation sequence will be described. In the CD-SEM, the inside of the LC is set to atmospheric pressure, a gate valve that controls opening and closing of an opening between the LC and the outside of the apparatus is opened, the wafer is taken into the LC, and then the gate valve is closed. Subsequently, the CD-SEM vacuum-evacuates the LC with a dry pump while the wafer is in the LC, and then vacuum-evacuates the LC to a high vacuum with the TMP.

Then, when the LC internal pressure reaches a predetermined value, the CD-SEM opens the gate valve between the LC and the SC, and conveys the wafer to the SC, which is already in a high-vacuum state. The wafer is inspected at the SC by being irradiated with an electron beam. After that, the wafer is taken out of the apparatus. The sequence at this time is generally the reverse of the sequence at the time of the loading described above. That is, in the CD-SEM, after the wafer is conveyed from the SC to the LC, the inside of the LC is made atmospheric pressure by the vent device while the wafer is in the LC. After that, the CD-SEM opens the gate valve that controls the opening and closing of the opening between the LC and the outside of the apparatus and takes the wafer out of the apparatus.

In recent years, the number of wafers releasing gas has been increasing due to the effects of manufacturing processes and the like. These are called outgas wafers. In particular, wafers for memory such as DRAM tend to release more gas. Therefore, there is a demand for a CD-SEM that can be used for next-generation outgas wafers in which the amount of gas released tends to increase.

Therefore, it is conceivable to use the charged particle beam apparatus of PTL 1. In the sequence of PTL 1, the degree of vacuum in the LC, which determines the conveyance timing from the LC to the SC, is switched between the normal wafer and the outgas wafer in the CD-SEM sequence described above. Specifically, in the case of an outgas wafer, the degree of vacuum in the LC is set to a higher vacuum (lower pressure) than in a normal wafer.

When the method of PTL 1 is used, when the outgas wafer depletes the gas release in the LC, the gas release after being conveyed to the SC can be reduced. However, in the method of PTL 1, even if the outgas wafer continues to release gas in the LC, the LC internal pressure may reach a high vacuum (low pressure) set for the outgas wafer by the TMP vacuum evacuation capability. In this case, the outgas wafer will continue to release gas even after being conveyed to the SC. As a result, the degree of vacuum in the SC may deteriorate and the performance of the apparatus may deteriorate.

Therefore, one object of the present disclosure is to provide a vacuum treatment apparatus and a vacuum treatment method that can reduce deterioration of the degree of vacuum in the conveyance destination vacuum chamber when a sample is conveyed between two vacuum chambers.

The above and other objects and novel features of the present disclosure will become apparent from the description of the specification and the accompanying drawings.

### Solution to Problem

A vacuum treatment apparatus of the present disclosure includes a first vacuum chamber, a second vacuum chamber connected to the first vacuum chamber via a valve, a vacuum pump that vacuum-evacuates the first vacuum chamber, a pressure gauge that measures an internal pressure of the first vacuum chamber, and a computer system. The computer system controls conveyance of a sample through the valve from the first vacuum chamber to the second vacuum chamber. At this time, the computer system stops the vacuum evacuation, which is being performed by the vacuum pump for a first duration of time, after having controlled the valve to close, measures the internal pressure of the first vacuum chamber by using the pressure gauge in a condition in which the vacuum evacuation is stopped, and controls the valve to open state when the measured internal pressure reaches a first reference value.

### Advantageous Effects of Invention

According to the present disclosure, when a sample is conveyed between two vacuum chambers, it is possible to reduce deterioration of the degree of vacuum in the conveyance destination vacuum chamber.

### BRIEF DESCRIPTION OF DRAWINGS

FIG. 1 is a schematic diagram illustrating a configuration example of a vacuum treatment apparatus according to Embodiment 1.

FIG. 2 is a flowchart illustrating an example of a control sequence executed by a control device serving as a comparative example in the vacuum treatment apparatus of FIG. 1.

FIG. 3 is a supplementary diagram illustrating the details of the control sequence of FIG. 2.

FIG. 4 is a supplementary diagram illustrating the details of the control sequence of FIG. 2.

FIG. 5 is a supplementary diagram illustrating the details of the control sequence of FIG. 2.

FIG. 6 is a supplementary diagram illustrating the details of the control sequence of FIG. 2.

FIG. 7 is a supplementary diagram illustrating the details of the control sequence of FIG. 2.

FIG. 8 is a flowchart illustrating an example of a control sequence different from that in FIG. 2 executed by a control device serving as a comparative example in the vacuum treatment apparatus of FIG. 1.

FIG. 9 is a flowchart illustrating an example of a control sequence executed by a control device according to Embodiment 1 in the vacuum treatment apparatus of FIG. 1.

FIG. 10 is a diagram illustrating an example of a transition of a degree of vacuum of an LC after stopping vacuum evacuation by a TMP in the vacuum treatment apparatus of FIG. 1.

FIG. 11A is a flowchart illustrating an example of a control sequence executed by a control device according to Embodiment 2 in the vacuum treatment apparatus of FIG. 1.

FIG. 11B is a flowchart following FIG. 11A.

FIG. 11C is a flowchart following FIG. 11B.

### DESCRIPTION OF EMBODIMENTS

Embodiments will be described below with reference to the accompanying drawings. In the accompanying drawings, functionally identical elements may be indicated by the same or corresponding number. Although the accompanying drawings illustrate embodiments in accordance with the principles of the present disclosure, they are for understanding the present disclosure and are not used to interpret the present disclosure in a limited way. The description in the specification is merely exemplary and is not intended to limit the scope or application of the claims of the present disclosure in any way.

Although the embodiments are described in sufficient detail to enable those skilled in the art to practice the disclosure, it should be understood that other implementations and forms are possible, and that the configuration and structure can be changed and various elements can be replaced without departing from the scope and spirit of the technical idea of the present disclosure. Therefore, the following description should not be construed as being limited to this.

### Embodiment 1

<<Configuration of Vacuum Treatment Apparatus>>

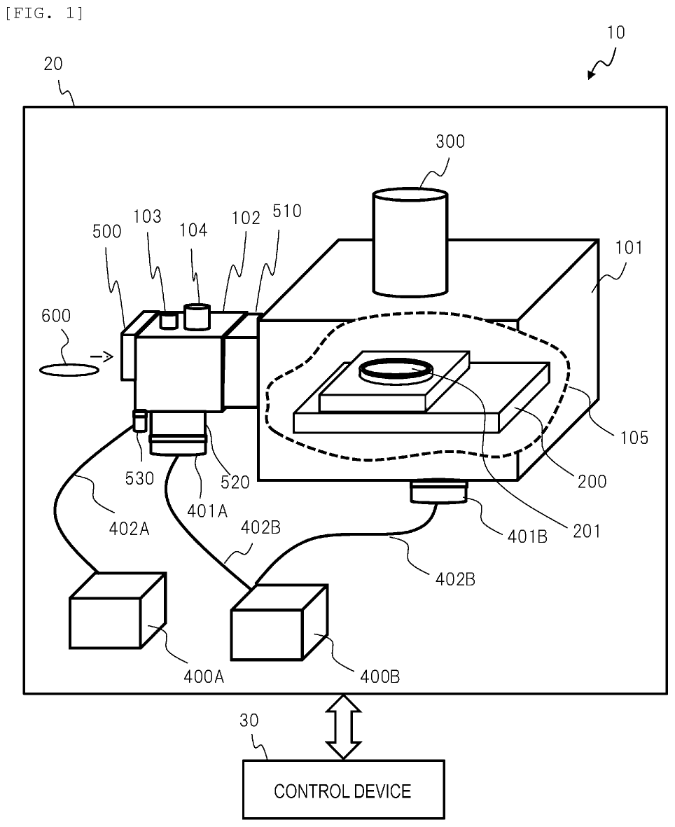

FIG. 1 is a schematic diagram illustrating a configuration example of a vacuum treatment apparatus according to Embodiment 1. In the specification, a case where the vacuum treatment apparatus is a charged particle beam apparatus, which is one of semiconductor inspection apparatuses, is taken as an example and in particular, the case where the apparatus is a CD-SEM is taken as an example. However, the vacuum treatment apparatus is not limited to the semiconductor inspection apparatus, and may be, for example, a semiconductor manufacturing apparatus such as a plasma CVD (Chemical Vapor Deposition) apparatus or a sputtering apparatus. Also, the semiconductor inspection apparatus may be, for example, a bright field microscope, a spectroscopic analyzer, an optical measurement device, an optical inspection device, or the like.

A vacuum treatment apparatus 10 illustrated in FIG. 1 includes an apparatus main body 20 and a control device 30. First, the apparatus main body 20 will be described. The apparatus main body 20 includes an LC 102 and an SC 101, which are vacuum chambers. The SC 101 is connected to the LC 102 via an LC-SC gate valve 510. The LC 102 serves as a front chamber when a wafer (that is, a sample) 600 to be inspected is taken into and out of the apparatus from outside. The SC 101 serves as an inspection room in which the wafer 600 is inspected. A dashed line 105 in the SC 101 is a notch provided for convenience to show the inside of the SC 101.

The SC 101 includes a holding mechanism 201 that holds the wafer 600 by electrostatic force or the like, a multi-axis stage 200 that has a function of driving the holding mechanism 201 in a plurality of directions within the SC 101, and an electron optical system (charged particle optical system) 300 that emits a charged particle beam (typically an electron beam). When inspecting the wafer 600 within the SC 101, the multi-axis stage 200 positions the wafer 600 held by the holding mechanism 201 with respect to the electron optical system 300. In this positioned state, the electron optical system 300 irradiates the wafer 600 with an electron beam.

Since the inspection using the electron beam is performed in this manner, the internal pressure of the SC 101 needs to be kept in a high vacuum state. On the other hand, the LC 102 plays a role of a front chamber when conveying the wafer 600 from the outside of the apparatus to the SC 101. For this reason, the internal pressure of the LC 102 fluctuates within the range from atmospheric pressure to high vacuum each time the wafer 600 is taken in and the inspected wafer 600 is taken out. Therefore, the LC 102 and SC 101 are equipped with TMPs 401A and 401B, respectively, which are vacuum pumps for creating a high vacuum state inside.

In addition, apart from the evacuation by the TMP 401A, the LC 102 includes a dry pump 400A, which is a vacuum pump responsible for vacuum evacuation from the atmosphere to a low vacuum, and a vent device 104 that ejects nitrogen (N 2) or the like for returning the inside of the LC to atmospheric pressure. Note that a dry pump 400B functions as an auxiliary pump for the TMPs 401A and 401B. A pipe 402B is arranged to connect between the dry pump 400B and the TMP 401B and between the dry pump 400B and the TMP 401A.

A pipe 402A connects between the dry pump 400A and the LC 102 via a pipe valve 530. A pressure gauge 103 measures the internal pressure of the LC 102. In the specification, the internal pressure of the LC 102 is measured as one method of obtaining the degree of vacuum of the LC 102, but other methods may be used as long as the degree of vacuum of the LC 102 can be obtained. A gate valve between inside and outside of the apparatus 500 is provided at an opening between the LC 102 and the outside of the apparatus. An LC-SC gate valve 510 is provided in an opening between the LC 102 and the SC 101. A TMP valve 520 is a vacuum valve and is provided at an opening between the LC 102 and the TMP 401A.

Here, the LC 102 has the smallest possible volume to allow for fast pressure fluctuations. Therefore, when comparing the two vacuum chambers, the LC 102 and the SC 101, the volume of the LC 102 is much smaller than that of the SC 101. Thus, by reducing the volume of the LC 102 and fluctuating the pressure quickly, the tact time for wafer inspection can be shortened.

Next, the control device 30 will be described. The control device 30 is implemented by, for example, a computer system including a processor and a memory. Specifically, the control device 30 may be, for example, a wiring board (in other words, a control board) on which various components including a processor and a memory are mounted. The control device 30 controls the apparatus main body 20 by the processor executing a control program stored in the memory. As one of the controls, the control device 30 controls conveyance of the wafer 600 from the LC 102 to the SC 101 via the LC-SC gate valve 510.

### Operation of Vacuum Treatment Apparatus (Comparative Example)

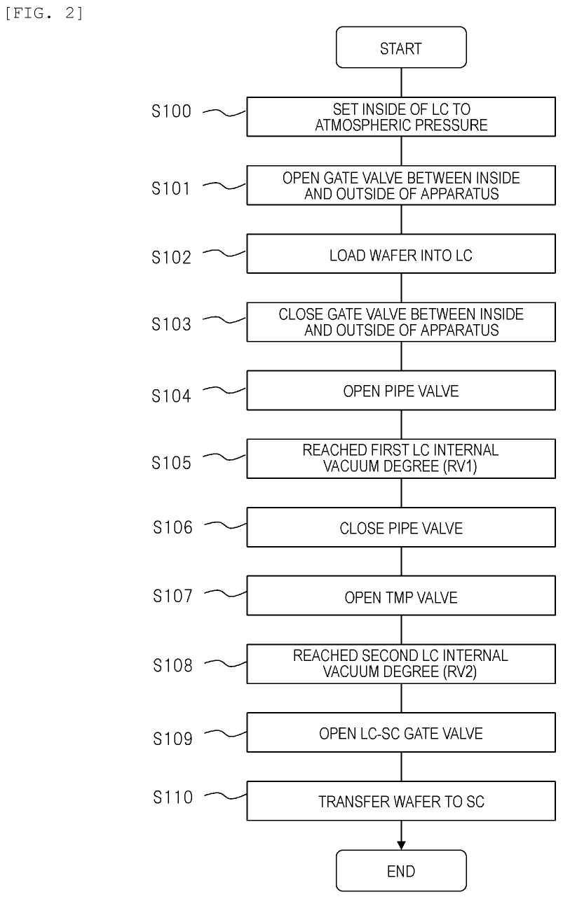

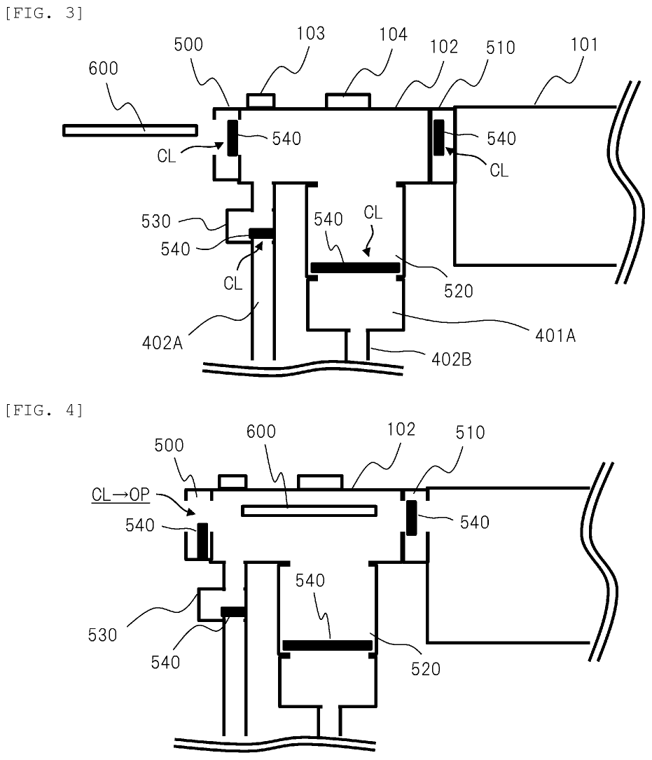

Here, to facilitate understanding of the present disclosure, using FIGS. 2 to 7, a general control sequence for conveying a normal wafer from outside the apparatus to the SC 101 and accompanying vacuum evacuation will be described step by step. FIG. 2 is a flowchart illustrating an example of a control sequence executed by a control device serving as a comparative example in the vacuum treatment apparatus of FIG. 1. FIGS. 3 to 7 are supplementary diagrams illustrating the details of the control sequence of FIG. 2.

FIG. 3 illustrates the processing procedure of step S100 in FIG. 1, and illustrates the preparatory stage before the wafer 600 is taken into from the outside. First, before step S100, the valve bodies 540 of the four valves facing the LC 102, namely, the gate valve between inside and outside of the apparatus 500, the LC-SC gate valve 510, the TMP valve 520, and the pipe valve 530, are all controlled to the closed state CL.

With the LC 102 sealed in this manner, the control device of the comparative example controls the vent device 104 to bring the inside of the LC 102 to atmospheric pressure with nitrogen (N 2) (step S100). Note that the internal pressure of the LC 102 is measured by the pressure gauge 103. Also, the two pipes 402A and 402B are connected to the dry pumps 400A and 400B illustrated in FIG. 1, respectively.

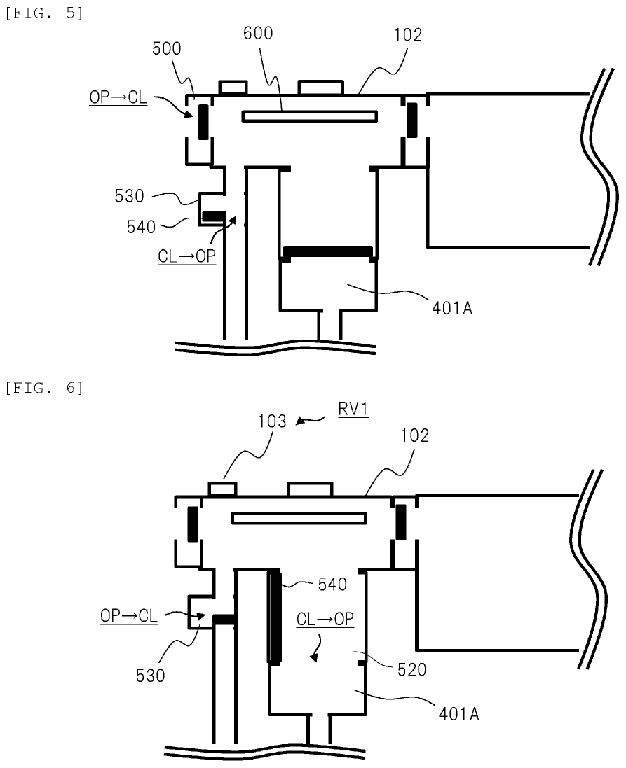

FIG. 4 illustrates the processing procedure of steps S101 and S102 in FIG. 1 and illustrates the state in which the wafer 600 is taken into the LC 102. Following the state of FIG. 3, the control device of the comparative example controls the gate valve between inside and outside of the apparatus 500 in the closed state CL to the open state OP (step S101). Then, the control device of the comparative example uses an apparatus inside/outside conveyance device (not illustrated) to load the wafer 600 from the gate valve between inside and outside of the apparatus 500 in the open state OP and place it on a wafer holder unit (not illustrated) in the LC 102 (step S102).

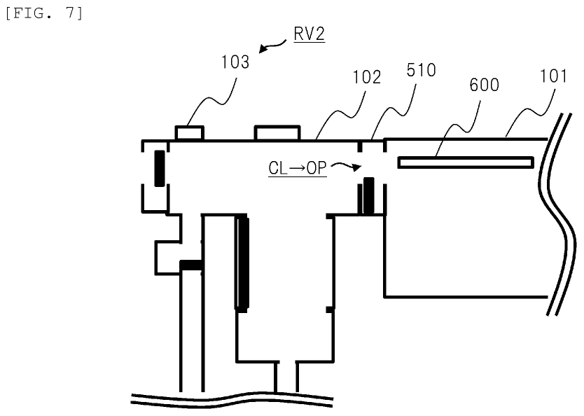

FIG. 5 illustrates the processing procedure of steps S103 and S104 in FIG. 1, and illustrates the procedure for vacuum-evacuating the LC 102 from the atmospheric condition. Since the TMP 401A cannot perform vacuum-evacuation from the atmospheric condition, it is necessary to perform vacuum evacuation with the dry pump 400A or the like illustrated in FIG. 1 in advance from the atmospheric condition to a low vacuum condition before beginning evacuation with the TMP 401A. Therefore, as illustrated in FIG. 5, following the state of FIG. 4, the control device of the comparative example controls the gate valve between inside and outside of the apparatus 500 in the open state OP to the closed state CL (step S103). Thereafter, the control device of the comparative example performs vacuum evacuation of the LC 102 by controlling the pipe valve 530 in the closed state CL to the open state OP (step S104).

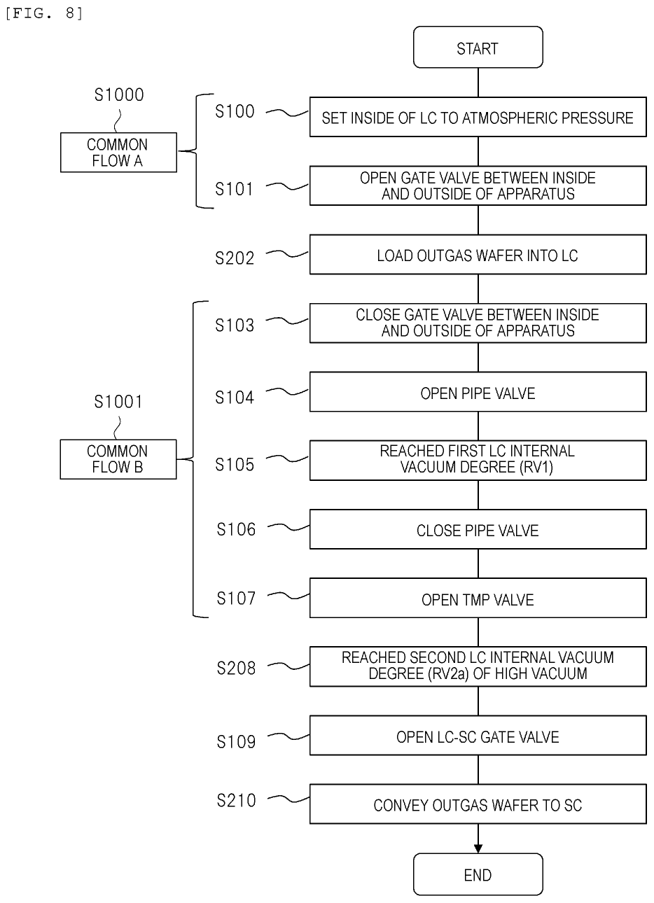

FIG. 6 illustrates the processing procedure of steps S105 to S107 in FIG. 1 and illustrates the procedure for vacuum-evacuating the LC 102 from low vacuum to high vacuum. If the state of FIG. 5 continues, the internal pressure of the LC 102 reaches a first LC internal vacuum degree (reference value) RV1, which is the TMP evacuation start pressure. When the pressure gauge 103 detects that the first LC internal vacuum degree RV1 has been reached (step S105), the control device of the comparative example controls the pipe valve 530 in the open state OP to the closed state CL (step S106). After that, the control device of the comparative example controls the TMP valve 520 in the closed state CL to the open state OP (step S107). As a result, the vacuum evacuation of the LC 102 by the TMP 401A is started.

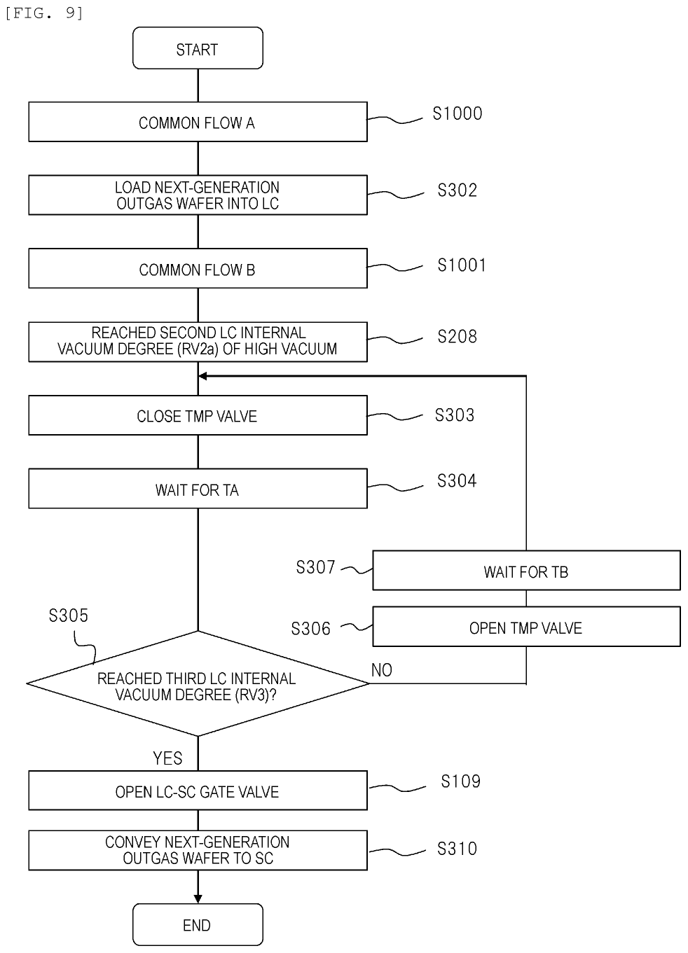

FIG. 7 illustrates the processing procedure of steps S108 to S110 in FIG. 1 and illustrates the procedure for conveying the wafer 600 from the LC 102 to the SC 101. After the state of FIG. 6, the internal pressure of the LC 102 reaches a second LC internal vacuum degree (reference value) RV2 which is lower (that is, a higher vacuum) than the first LC internal vacuum degree (reference value) RV1.

When the pressure gauge 103 detects that the second LC internal vacuum degree RV2 has been reached (step S108), the control device of the comparative example controls the LC-SC gate valve 510 in the closed state CL to the open state OP (Step S109). After that, the control device of the comparative example conveys the wafer 600 to the SC 101 through the LC-SC gate valve 510 in the open state OP (step S110) by using an LC-SC conveyance device (not shown). At this time, the SC 101 is in a high vacuum state in advance. After conveying the wafer 600, the control device of the comparative example controls the LC-SC gate valve 510 in the open state OP to the closed state CL.

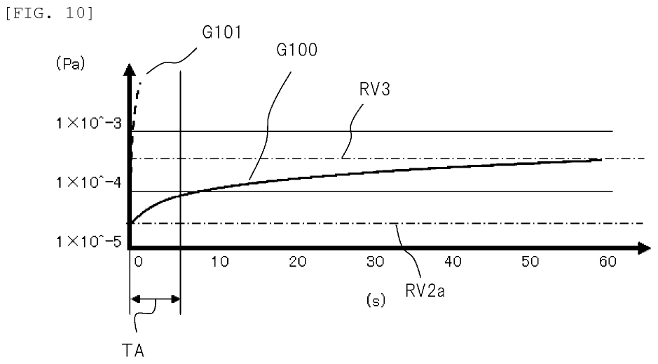

The control sequence as described above is applicable when targeting a normal wafer 600. However, there are various types of wafers, and for example, some wafers themselves release gas due to the influence of the manufacturing process. These are called outgas wafers. When targeting outgas wafers, it is conceivable to use, for example, a control sequence as illustrated in FIG. 8, as in PTL 1.

FIG. 8 is a flowchart illustrating an example of a control sequence different from that in FIG. 2 executed by a control device serving as a comparative example in the vacuum treatment apparatus of FIG. 1. In FIG. 8, step S102 is replaced with step S202, and step S108 is replaced with step S208, as compared with FIG. 2. In step S202, an outgas wafer (sample) is loaded into the LC 102 instead of a normal wafer. In step S208, it is detected that the second LC internal vacuum degree (reference value) RV2a of high vacuum has been reached.

In this way, the characteristic of FIG. 8 is that the detection of reaching the second LC internal vacuum degree for determining the conveyance timing from the LC 102 to the SC 101 is performed at the second LC internal vacuum degree RV2a which is a higher vacuum (low pressure) than the second LC internal vacuum degree RV2 in FIG. 2. This is one way to reduce gas release after the outgas wafer is conveyed to the SC 101 by depleting the gas while the outgas wafer is in the LC 102. Note that the second LC internal vacuum degrees RV2 and RV2a are values within the pressure range based on the vacuum evacuation capability of the TMP.

Here, both the detection in step S108 of FIG. 2 and the detection in step S208 of FIG. 8 are performed while the TMP valve 520 is controlled to the open state OP in step S107. Therefore, the LC internal vacuum degree is detected in parallel with the vacuum evacuation by the TMP 401A. Note that steps S100 and S101 are referred to as a common flow A (step S1000), and steps S103 to S107 are referred to as a common flow B (step S1001), which are common in FIGS. 2 and 8, for the convenience of later description.

### Operation of Vacuum Treatment Apparatus (Embodiment 1)

On the other hand, in recent years, the number of outgas wafers in which the depletion of gas is difficult has been increasing. When such a next-generation outgas wafer is treated by the method illustrated in FIG. 8, the degree of vacuum can be checked in parallel with the vacuum evacuation by the TMP 401A. Therefore, the second LC internal vacuum degree RV2a of high vacuum may be reached in equilibrium between gas release and vacuum evacuation in step S208. In this case, since the gas is not depleted, the next-generation outgas wafer continues to release gas even after being conveyed to the SC 101, and the degree of vacuum of the SC 101, which should maintain a high vacuum, deteriorates.

The deterioration of the degree of vacuum of the SC 101 causes, for example, a problem called contamination, in which organic substances are burned onto the next-generation outgas wafer to be inspected by the electron beam, and in some cases, it may lead to a situation in which the electron beam cannot be irradiated. Moreover, since the SC 101 has a much larger volume than the LC 102, it takes a long time to recover when the degree of vacuum deteriorates. Therefore, it is beneficial to use the method of Embodiment 1 described below.

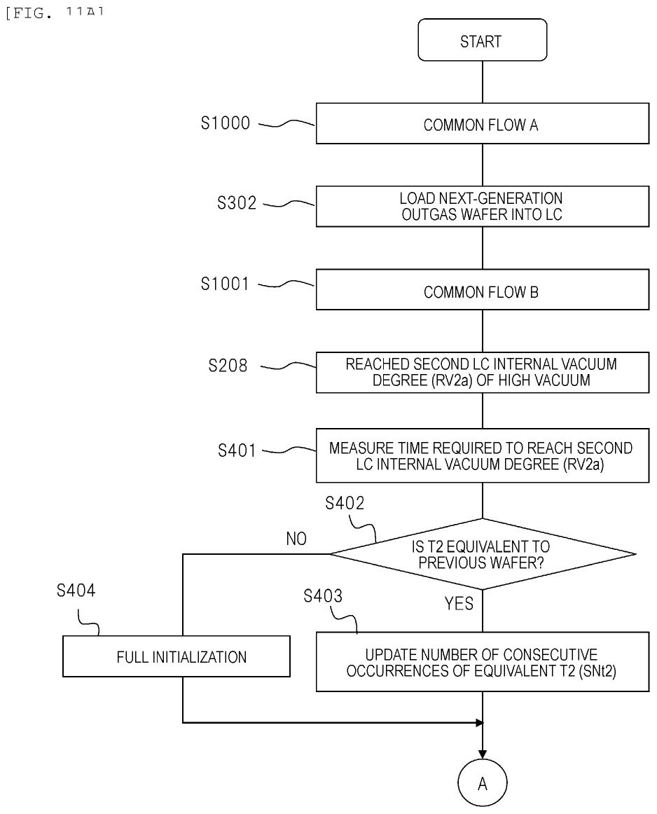

FIG. 9 is a flowchart illustrating an example of a control sequence executed by a control device according to Embodiment 1 in the vacuum treatment apparatus of FIG. 1. In FIG. 9, the control device 30 of Embodiment 1 first executes the common flow A in step S1000, and then loads the next-generation outgas wafer (sample) into the LC 102 (step S302). Subsequently, the control device 30 executes the common flow B in step S1001.

Subsequently, when the control device 30 detect reaching the second LC internal vacuum degree RV2a of high vacuum by using the pressure gauge 103, that is, when the internal pressure of the LC 102 is equal to or lower than the second LC internal vacuum degree RV2a (step S208), the control device 30 controls the TMP valve 520 in the open state OP to the closed state CL (step S303). Thereby, the control device 30 stops the vacuum evacuation of the LC 102 by the TMP 401A. With this vacuum evacuation stopped, the control device 30 waits for a wait time TA (step S304).

After that, the control device 30 measures the internal pressure of the LC 102 using the pressure gauge 103, and determines whether the measured internal pressure reaches a third LC internal vacuum degree (reference value) RV3, that is, whether the measured internal pressure is equal to or less than the third LC internal vacuum degree RV3 (step S305). Here, when the measured internal pressure reaches the third LC internal vacuum degree RV3, the control device 30 determines that the gas has been depleted, and proceeds to step S109. Then, in step S109, the control device 30 controls the LC-SC gate valve 510 in the closed state CL to the open state OP, and in step S310, the next-generation outgas wafer is conveyed to the SC 101 via the LC-SC gate valve 510.

On the other hand, in step S305, if the measured internal pressure does not reach the third LC internal vacuum degree RV3, that is, if the measured internal pressure is higher than the third LC internal vacuum degree RV3, the control device 30 determines that the gas is not depleted and controls the TMP valve 520 in the closed state CL to the open state OP to restart vacuum evacuation (step S306). After that, the control device 30 performs the vacuum evacuation for the wait time TB (step S307), and then returns to step S303.

As described above, the control device 30 controls the LC-SC gate valve 510 to the closed state CL, stops the vacuum evacuation by the TMP 401A, which has been performed for a time until the second LC internal vacuum degree RV2a is reached, in step S303, and measures the internal pressure of LC 102 in this stopped state in step S305. Then, when the measured internal pressure reaches the third LC internal vacuum degree RV3, the control device 30 controls the LC-SC gate valve 510 in the closed state CL to the open state OP (step S109).

On the other hand, if the internal pressure measured in step S305 has not reached the third LC internal vacuum degree RV3, the control device 30 stops the vacuum evacuation by the TMP 401A after performing for the wait time TB (steps S307 and S303). Similarly, the control device 30 repeats the loop processing (steps S303 to S307) of measuring the internal pressure of the LC 102 in a condition in which the vacuum evacuation is stopped until the measured internal pressure reaches the third LC internal vacuum degree RV3.

Here, the user can set the wait time TA in step S304 and the wait time TB in step S307 to any value. Furthermore, the user can set the third LC internal vacuum degree RV3 to any value. However, these values need to be determined appropriately so that the determination in step S305 can be performed accurately. This point will be described below.

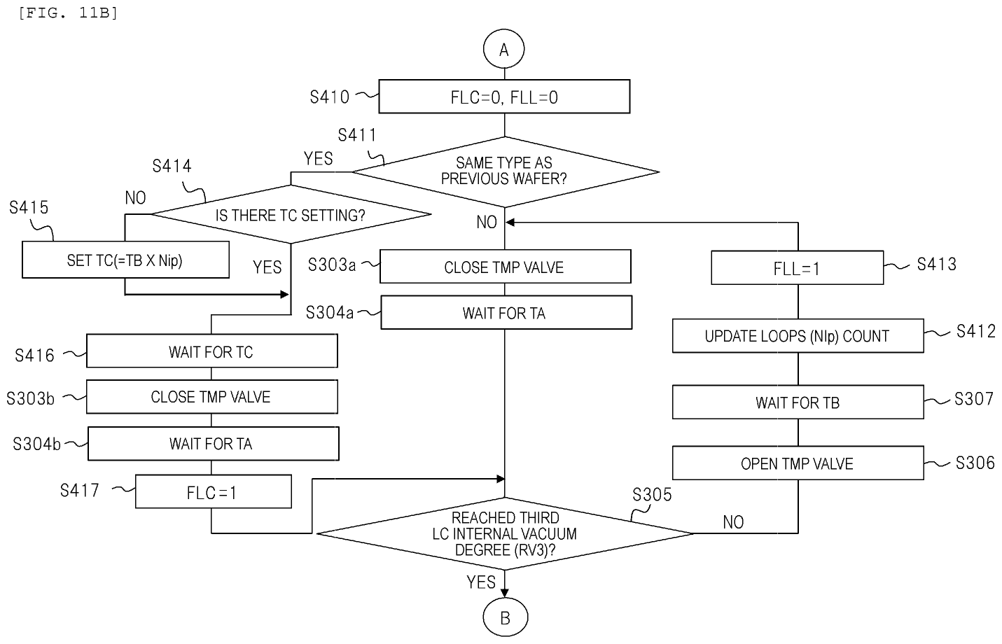

FIG. 10 is a diagram illustrating an example of a transition of the degree of vacuum of the LC after stopping vacuum evacuation by the TMP in the vacuum treatment apparatus of FIG. 1. If the gas of the next-generation outgas wafer is depleted, the internal pressure of the LC 102 slowly deteriorates from the second LC internal vacuum degree RV2a, as indicated in a plot G100 for the depleted case. On the other hand, if the gas is not depleted, the internal pressure of the LC 102 abruptly deteriorates from the second LC internal vacuum degree RV2a, as indicated in a plot G101 for a case in which the gas is not depleted. By stopping the vacuum evacuation by the TMP 401A in this way, there is a clear difference in the characteristics of the transition of the degree of vacuum depending on whether the gas is depleted or not.

The wait time TA in step S304 of FIG. 9 is set, for example, to the time required for the actual opening and closing operation of the TMP valve 520. As a specific example, the wait time TA is set to several seconds, for example. FIG. 10 illustrates such wait time TA. When the wait time TA has passed, there is a clear pressure difference between the plot G100 when depleted and the plot G101 when not depleted. Therefore, by setting the third LC internal vacuum degree RV3 in step S305 of FIG. 9 to a value that is higher by a predetermined amount with respect to the second LC internal vacuum degree RV2a, as illustrated in FIG. 10, for example, the determination in step S305 of FIG. 9 can be made accurately.

Also, the wait time TB, which is the time for vacuum evacuation again in step S307 of FIG. 9 is appropriately determined according to, for example, the type or the like of the next-generation outgas wafer. Normally, the wait time TB is sufficiently longer than the wait time TA, and can be, for example, several tens of seconds or more. Thus, by appropriately setting the wait times TA and TB and the third LC internal vacuum degree RV3, the presence or absence of gas depletion for various types of next-generation outgas wafers can be accurately determined. The third LC internal vacuum degree RV3 is desirably set for each apparatus in consideration of machine differences of apparatuses and is also desirably updated periodically in consideration of changes over time.

<<Various Modifications>>

In steps S303 to S307 of FIG. 9, the control device 30 repeatedly performs the opening and closing operations of the TMP valve 520. However, instead of opening and closing operations of the TMP valve 520, the control device 30 may repeatedly adjust the degree of opening. Further, in steps S303 to S307, the control device LC 102 performed loop processing until the degree of vacuum of the LC 102 reached the third LC internal vacuum degree RV3. In other words, the control device LC 102 determined whether to proceed to step S109 based on the result of comparison between the degree of vacuum of the LC 102 and a predetermined threshold value. However, the control device 30 may determine whether to proceed to step S109 based on the amount of change in the degree of vacuum of the LC 102 or the response characteristic during the period of the loop processing.

That is, in the flow of FIG. 9, the open state of the TMP valve 520 may not be maintained in the period until the process proceeds to step S109, but the opening and closing operation of the TMP valve 520 or the adjustment of the degree of the opening may be repeated. As a result, the control device 30 can particularly reflect the degree of vacuum of the LC 102 when the TMP valve 520 is in the closed state or when the degree of the opening is slightly adjusted, and then, determine whether to proceed to step S109.

### Main Effects of Embodiment 1

As described above, by using the method of Embodiment 1, when a sample is conveyed between two vacuum chambers, it is possible to reduce deterioration of the degree of vacuum in the conveyance destination vacuum chamber. As a result, the performance of the apparatus can be enhanced. Specifically, for example, it is possible to reduce the occurrence of contamination in the conveyance destination vacuum chamber, and it is possible to inspect the sample in the SC 101 with high accuracy. In addition, the wait time for the degree of vacuum to recover is unnecessary in the conveyance destination vacuum chamber having a large capacity, and the throughput of the apparatus can be improved.

### Embodiment 2

### Operation of Vacuum Treatment Apparatus (Embodiment 2)

In Embodiment 1, if the wait time TB in step S307 of FIG. 9 is excessively shortened, opening and closing of the TMP valve 520 will be repeated many times until the gas is depleted. In this case, the TMP valve 520 can cause the period until it reaches the end of its life to be shortened due to the increased number of times of operations. Furthermore, each time the gas depletion determination is made, the vacuum evacuation of the LC 102 by the TMP 401A stops, which increases the time required to reach gas depletion and, consequently, can reduce the throughput of the apparatus. On the other hand, if the wait time TB is excessively lengthened, the vacuum evacuation time again becomes excessive, and in this case also, the throughput of the apparatus may decrease. Therefore, it is beneficial to use the following method.

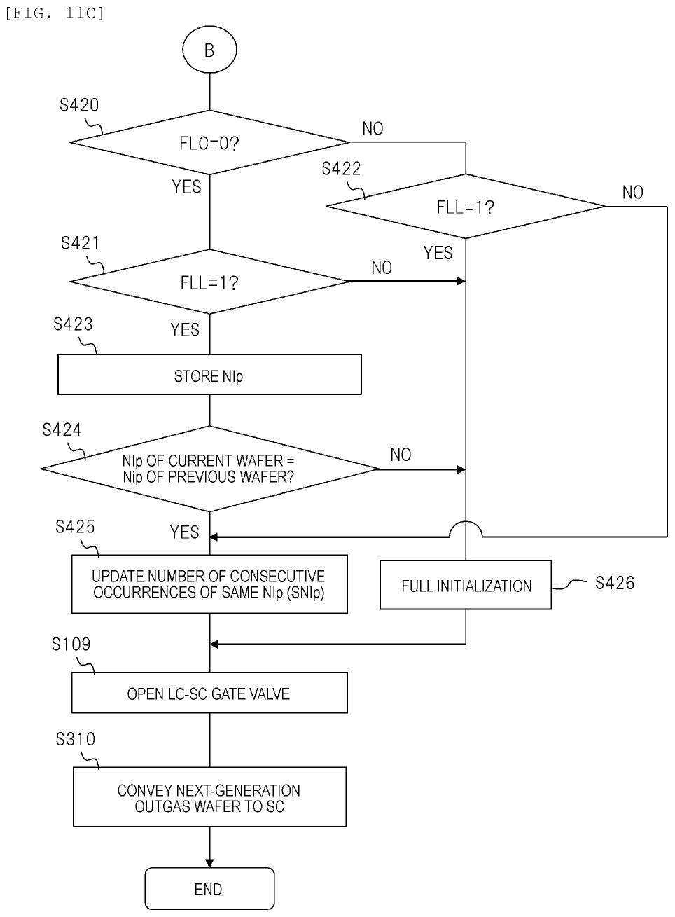

FIG. 11A is a flowchart illustrating an example of a control sequence executed by a control device according to Embodiment 2 in the vacuum treatment apparatus of FIG. 1. FIG. 11B is a flowchart following FIG. 11A, and FIG. 11C is a flowchart following FIG. 11B. For example, outgas wafers manufactured by the same manufacturing process often have similar characteristics and the vacuum evacuation time required for gas depletion often has a similar tendency (required time). In the method of Embodiment 2, the vacuum evacuation time required for gas depletion is measured for a certain type of wafer, and when the same type of wafer is treated, waiting that reflects the measured vacuum evacuation time is inserted, for example, between steps S208 and S303 in FIG. 9.

First, outlines of FIGS. 11A, 11B, and 11C will be described. The control device 30 measures, with reference to step S412 in FIG. 11B, the total duration of time of vacuum evacuation until the internal pressure reaches the third LC internal vacuum degree (reference value) RV3 for the next-generation outgas wafer (sample) in which the vacuum evacuation loop processing occurred while measuring the internal pressure in step S305 of FIG. 11B. Then, when a wafer of the same type as the measured next-generation outgas wafer is targeted (step S411 in FIG. 11B), the control device 30 inserts waiting in step S416 in FIG. 11B to reflect the measured total duration of time in the first vacuum evacuation time before the loop processing occurs.

In addition, the control device 30 measures a required time-to-reach T2 in step S401 of FIG. 11A as one of the conditions for determining whether the wafers are of the same type in step S411. The required time-to-reach T2 is, for example, the time required for the internal pressure of the LC 102 to reach the second LC internal vacuum degree (reference value) RV2a from a predetermined start time. The predetermined start time is typically the time when the TMP valve 520 is opened in step S107 in FIG. 8, but is not limited to this, and may be any step before step S107. In step S411 of FIG. 11B, the control device 30 determines that wafers with the same required time-to-reach T2 are wafers of the same type.

Furthermore, the control device 30 also determines, in step S305 of FIG. 11B, whether the internal pressure measured with the vacuum evacuation stopped reaches the third LC internal vacuum degree RV3 when targeting the wafer via the waiting in step S416 of FIG. 11B. Then, when the internal pressure measured in the wafer has reached the third LC internal vacuum degree RV3 and the wafer is the previous wafer, the control device 30 determines whether the required time-to-reach T2 of the previous wafer and the current wafer to be treated subsequently is equivalent in step S401 of FIG. 11A. If the required time-to-reach T2 is equivalent, the control device 30 determines that the current wafer is of the same type as the previous wafer in step S411 of FIG. 11A.

Details of FIGS. 11A, 11B, and 11C will be described. In FIG. 11A, as in the case of FIG. 9, through steps S1000, S302, and S1001, the internal pressure of the LC 102 reaches the second LC internal vacuum degree RV2a (step S208). At this time, the control device 30 measures the required time-to-reach T2 required to reach the second LC internal vacuum degree RV2a from a predetermined start time (step S401). In general, the greater the amount of gas released from the next-generation outgas wafer, the longer the required time-to-reach T2, and when the wafers are of the same type, the required time-to-reach T2 is also equivalent.

In the subsequent step S402, the control device 30 determines whether the required time-to-reach T2 is equivalent between the previous wafer and the current wafer. When the required time-to-reach T2 is equivalent, the control device 30 updates the number of consecutive occurrences SNt2 of the equivalent T2 (step S403). For example, the number of consecutive occurrences SNt2 is n when n consecutive wafers have the equivalent required time-to-reach T2.

On the other hand, if the required time-to-reach T2 is not equivalent in step S402, the control device 30 performs a full initialization (step S404). Specifically, the control device 30 resets the number of consecutive occurrences SNt2 in step S403 and the number of consecutive occurrences SNlp, which will be described later, in step S425 of FIG. 11C to 0, and change the setting of the wait time Tc, which will be described later, in step S414 of FIG. 11B to none. In addition, the control device 30 sets both flags FLC and FLL, which will be described later, to 0.

After step S403 or step S404 in FIG. 11A, the control device 30 sets both flags FLC and FLL for determining the path in the flow to 0, as illustrated in FIG. 11B (step S410). Subsequently, the control device 30 determines whether the current wafer is the same type as the previous wafer (step S411). This determination condition will be described later. If the wafer is not of the same type as the previous wafer, as in the case of FIG. 9, the control device 30 controls the TMP valve 520 to the closed state CL (step S303a), waits for the wait time TA (step S304a), and determines whether the third LC internal vacuum degree RV3 has been reached (step S305).

If the third LC internal vacuum degree RV3 has not been reached in step S305, the control device 30 controls the TMP valve 520 to the open state OP (step S306) as in the case of FIG. 9, the LC 102 is again vacuum evacuated in the wait time TB (step S307). After that, the control device 30 returns to step S303a through the processing of steps S412 and S413, repeats the loop processing until the third LC internal vacuum degree RV3 is reached, as in the case of FIG. 9 and then proceeds to step S420 of FIG. 11C.

During this loop processing, the control device 30 updates the number of loops Nlp in step S412 (step S412). The number of loops Nlp is m when the waiting in step S307 is performed m times due to the loop processing. Further, in step S413, the control device 30 changes the flag FLL to 1 (step S413). The flag FLL indicates that loop processing has been executed.

On the other hand, if the current wafer is of the same type as the previous wafer in step S411, the control device 30 determines whether the wait time TC is set (step S414). If the wait time TC is set, the control device 30 extends the current vacuum evacuation by the wait time TC (step S416). If the wait time TC is not set in step S414, the control device 30 sets the wait time TC by, for example, multiplying the wait time TB in step S307 by the number of loops Nlp obtained in step S412 (step S415), and the process proceeds to step S416. The number of loops Nlp at this time represents the number of times it was executed on the previous wafer.

After that, as in the case of FIG. 9, the control device 30 controls the TMP valve 520 to the closed state CL (step S303b), waits for the wait time TA (step S304b), and determines whether the third LC internal vacuum degree RV3 has been reached (step S305). Further, when the current vacuum evacuation is extended in step S416, the control device changes the flag FCL indicating this to 1 (step S417).

Subsequently, in steps S420, S421, and S422 of FIG. 11C, the control device 30 determines the states of flags FLC and FLL. First, when FLC=0 & FLL=1, that is, when intermittent processing of the vacuum evacuation accompanying the loop processing is performed without extending the current vacuum evacuation, the control device stores the final number of loops Nlp updated in step S412 of FIG. 11B (step S423).

Then, the control device 30 determines whether the number of loops Nlp stored for the current wafer matches the number of loops Nlp already stored for the previous wafer (step S424). If the number of loops Nlp matches in step S424, the number of consecutive occurrences SNlp of the same Nlp is updated (step S425). For example, the number of consecutive occurrences SNlp is n when the number of loops Nlp matches for n consecutive wafers. On the other hand, if the number of loops Nlp does not match in step S424, the control device 30 performs full initialization as in step S404 of FIG. 11A (step S426).

That is, in the example of this flowchart, for example, the required time-to-reach T2 in step S401 of FIG. 11A is equivalent for the first to j-th (j is an integer of 2 or more) wafers and the number of loops Nlp in FIG. 11B matches, the j wafers are considered to be of the same type, and it is determined that the j+1-th wafer is highly likely to be of the same type. Then, if the j+1-th wafer also has the equivalent required time-to-reach T2 as the j-th wafer, the j+1-th wafer is determined to be of the same type, and the path of step S416 in FIG. 11B is selected.

Therefore, in step S411 of FIG. 11B, the control device 30 determines that the current wafer is of the same type as the previous wafer when the number of consecutive occurrences SNt2 of equivalent T2 is j+1 (j is an integer equal to 2 or more) and the number of consecutive occurrences SNlp of the same Nlp is j. At this time, the minimum value of j, that is, the number of consecutive occurrences at which the next wafer is determined to have a high possibility of being of the same type is freely determined.

Further, when the state in which the required time-to-reach T2 is continuously equivalent is interrupted, a full initialization is performed in step S404 of FIG. 11A. Similarly, when the state in which the number of loops Nlp is continuously matched is interrupted, a full initialization is performed in step S426 via step S424 in FIG. 11C. If a full initialization is performed in any of these, the state of the first wafer described above is restored.

Referring back to steps S420, S421, and S422 in FIG. 11C, when FLC=1 & FLL=1, that is, when the intermittent processing of the vacuum evacuation accompanying the loop processing is performed even though the current vacuum evacuation is extended, the control device performs a full initialization in step S426. On the other hand, when FLC=1 & FLL=0, that is, when the current vacuum evacuation is extended and the intermittent processing of the vacuum evacuation accompanying the loop processing is not performed, the control device assumes that the condition of step S424 is satisfied, and updates the number of consecutive occurrences SNlp of the same Nlp in step S425. This enables the control device 30 to make a correct determination based on the number of consecutive occurrences SNt2 and SNlp in step S411 of FIG. 11B even when the current vacuum evacuation is extended.

After the process of step S425 or step S426, the control device controls the LC-SC gate valve 510 to the open state OP (step S109), as in the case of FIG. 9. Then, the control device 30 conveys the next-generation outgas wafer to the SC 101 via the LC-SC gate valve 510 (step S310).

Note that in step S402 of FIG. 11A, the user can set any range in which the required time-to-reach T2 is considered equivalent. Also, as in the case of FIG. 9, the wait time TB in step S307 of FIG. 11B can also be freely set by the user. Such user settings make it possible to build a flowchart that reflects the user's intentions. For example, if the user desires to select the path of step S416 as much as possible even though a slightly excessive vacuum evacuation time may occur, the user may set a wide range to some extent in which the required time-to-reach T2 is regarded as equivalent, and set the wait time TB longer.

Also, here, in step S424 of FIG. 11C, the match or mismatch of the number of loops Nlp was determined, but in some cases, an error tolerance of, for example, ±1 may be set for this determination condition. This is because an error may occur in the number of loops Nlp even for wafers of the same type, depending on the length of the wait time TB and at what point in the wait time TB the gas is depleted. For the same reason, an error tolerance of about ±1 may be provided for the number of consecutive occurrences SNlp of the same Nlp, which is the determination condition in step S411 of FIG. 11B.

<<Various Modifications>>

Although not illustrated, for example, after step S310 in FIG. 11C, a branch may be provided to additionally determine whether the gas is depleted based on a change in the degree of vacuum within the SC 101. Then, if it is determined that the gas continues to be released at this branch, a full initialization may be performed in the same manner as in steps S404 and S426.

Also, for example, if gas release continues for an extremely long time, there is a possibility that some kind of abnormality has occurred in the apparatus. Therefore, the control device 30 may determine the upper limit of the number of repetitions of the above-described loop processing based on user settings. Specifically, for example, after step S412 in FIG. 11B, a branch for determining whether the number of loops Nlp has reached the upper limit set by the user may be added. In this branch, when the number of loops Nlp reaches the upper limit, that matter may be notified to the user, or the apparatus operation may be forcibly terminated. At this time, the control device 30 may forcibly terminate the apparatus operation according to a command from the user.

Furthermore, in FIGS. 11A, 11B, and 11C, on the premise that the type of wafer is unknown, it is determined in step S411 of FIG. 11B whether the current wafer is of the same type as the previous wafer. However, if the type of wafer is known in advance, for example, by inputting a wafer identifier in advance, the control device 30 may select the path on the step S416 side of FIG. 11B without determining the equivalence of the required time-to-reach T2. The wait time TC at this time is determined by reflecting the total time of vacuum evacuation measured for wafers of the same type in the past.

### Main Effects of Embodiment 2

As described above, by using the method of Embodiment 2, it is possible to reduce the number of times the TMP valve 520 is opened and closed, in addition to obtaining the same effects as those described in Embodiment 1. As a result, for example, the life of the apparatus can be extended and the throughput of the apparatus can be improved.

### Embodiment 3

### Operation of Vacuum Treatment Apparatus (Embodiment 3)

The control device 30 may use the control sequences of FIGS. 2, 8, and 9 (or FIGS. 11A, 11B, and 11C) according to the type of wafer (sample). That is, the control device 30 may switch between measuring the internal pressure of the LC 102 with the vacuum evacuation stopped or with the vacuum evacuation in progress, depending on the type of wafer.

Specifically, the control device 30 measures, for example, the time (called T3) until the second LC internal vacuum degree RV2, which was used in step S108 in FIG. 2 is reached from the predetermined start point, as in steps S208 and S401 in FIG. 11A. Then, the control device 30 compares the time T3 with predetermined comparison times Tc1 and Tc2 (Tc1<Tc2).

If the comparison result is T3 Tc1, the control device 30 executes the processes after step S109 in FIG. 2. If the comparison result is Tc1<T3≤Tc2, the control device 30 waits until the high-vacuum second LC internal vacuum degree RV2a in step S208 in FIG. 8 is reached, and then executes the processes from step S109 in FIG. 8. If the comparison result is Tc2<T3, the control device 30 waits until the high-vacuum second LC internal vacuum degree RV2a in step S208 in FIG. 9 is reached, and then executes the processes from step S303 in FIG. 9.

When using such a method, the control device 30 may, for example, be fixed to any one of the three control sequences described above, or may perform automatic switching within any two of the three control sequences, according to a user's request. Further, as described in Embodiment 2, when the type of wafer is known in advance, the control device 30 may automatically select one of the three control sequences without measuring the time T3, according to the type of wafer.

### Main Effects of Embodiment 3

As described above, by using the method of Embodiment 3, for example, it is possible to improve apparatus throughput and extend apparatus life, in addition to obtaining various effects similar to those described in Embodiment 1. Specifically, in the case of normal wafers, there is no need to wait until the high-vacuum second LC internal vacuum degree RV2a is reached. Further, the number of times the TMP valve 520 is opened and closed can be reduced when targeting an outgas wafer, which is easily depleted of gas, rather than an outgas wafer, which is difficult to deplete of gas.

### REFERENCE SIGNS LIST

10: vacuum treatment apparatus
20: apparatus main body
30: control device
101: SC (vacuum chamber)
102: LC (vacuum chamber)
103: pressure gauge
300: electron optical system
401A, 401B: TMP
510: LC-SC gate valve
520: TMP valve
600: wafer
CL: closed state
Nlp: number of loops
OP: open state
RV1: first LC internal vacuum degree (reference value)
RV2, RV2a: second LC internal vacuum degree (reference value)
RV3: third LC internal vacuum degree (reference value)
TA, TB, TC: wait time

1-15. (canceled)

16. A vacuum treatment apparatus comprising:
a first vacuum chamber including a first gate valve to be opened and closed depending on conveyance of a sample to/from outside the apparatus;
a second vacuum chamber connected to the first vacuum chamber via a second gate valve;
a vacuum pump that vacuum-evacuates the first vacuum chamber;
a pressure gauge that measures an internal pressure of the first vacuum chamber; and
a computer system that controls conveyance of the sample through the second gate valve from the first vacuum chamber to the second vacuum chamber, wherein
the computer system stops the vacuum evacuation, which is being performed by the vacuum pump for a first duration of time, after having controlled the second gate valve to a closed state, measures the internal pressure of the first vacuum chamber by using the pressure gauge in a condition in which the vacuum evacuation is stopped, and controls the second gate valve to an open state if the measured internal pressure reaches a first reference value,
if the measured internal pressure does not reach the first reference value, the computer system repeats a loop processing of stopping the vacuum evacuation after having been performed by the vacuum pump for a second duration of time and measuring the internal pressure of the first vacuum chamber in a condition in which the vacuum evacuation is stopped, until the measured internal pressure reaches the first reference value.

17. The vacuum treatment apparatus according to claim 16, wherein
the first vacuum chamber is a load lock chamber.

18. The vacuum treatment apparatus according to claim 17, wherein
the computer system measures a total duration of time of the vacuum evacuation required for the measured internal pressure to reach the first reference value for a first sample in which the loop processing has occurred, and reflects the total duration of time in the first duration of time when targeting a sample of the same type as the first sample.

19. The vacuum treatment apparatus according to claim 18, wherein
the computer system measures a third duration of time required for the internal pressure of the first vacuum chamber to reach a second reference value higher than the first reference value from a predetermined start time, and determines whether the sample is of the same type as the first sample based on the third duration of time.

20. The vacuum treatment apparatus according to claim 19, wherein
the computer system
for a second sample, stops the vacuum evacuation after having been performed by the vacuum pump for the first duration of time reflecting the total duration of time, and determines whether the internal pressure measured in a condition in which the vacuum evacuation is stopped reaches the first reference value, and
determines that a third sample is of the same type as the second sample if the measured internal pressure in the second sample reaches the first reference value and the third durations of time are equivalent for the second sample and the third sample that is treated following the second sample.

21. The vacuum treatment apparatus according to claim 17, wherein
the computer system defines an upper limit for the number of repetitions of the loop processing based on user settings.

22. The vacuum treatment apparatus according to claim 16, wherein
the vacuum pump is a turbomolecular pump (TMP).

23. The vacuum treatment apparatus according to claim 16, wherein
the computer system can switch between measuring the internal pressure of the first vacuum chamber in a condition in which the vacuum evacuation is stopped or in a condition in which the vacuum evacuation is being performed, depending on the type of the sample.

24. The vacuum treatment apparatus according to claim 16, wherein
the vacuum treatment apparatus is a charged particle beam apparatus that irradiates the sample conveyed to the second vacuum chamber with a charged particle beam.

25. The vacuum treatment apparatus according to claim 16, wherein
the computer system controls conveyance of the sample from the first vacuum chamber to the second vacuum chamber, based on the amount of change or response characteristic of the measured internal pressure within the loop processing.

26. A vacuum treatment method for a vacuum treatment apparatus including:
a first vacuum chamber including a first gate valve to be opened and closed depending on conveyance of a sample to/from outside the apparatus;
a second vacuum chamber connected to the first vacuum chamber via a second gate valve;
a vacuum pump that vacuum-evacuates the first vacuum chamber; and
a pressure gauge that measures an internal pressure of the first vacuum chamber,
wherein when the conveyance of the sample from the first vacuum chamber to the second vacuum chamber via the second gate valve is controlled, the vacuum evacuation which is being performed by the vacuum pump for a first duration of time is stopped after having controlled the valve to close, the internal pressure of the first vacuum chamber is measured by using the pressure gauge in a condition in which the vacuum evacuation is stopped, and the second gate valve is controlled to an open state if the measured internal pressure reaches a first reference value, and
if the measured internal pressure does not reach the first reference value, a loop processing of stopping the vacuum evacuation after having been performed by the vacuum pump for a second duration of time, and measuring the internal pressure of the first vacuum chamber in a condition in which the vacuum evacuation is stopped is repeated until the measured internal pressure reaches the first reference value.

27. The vacuum treatment method according to claim 26, wherein
the first vacuum chamber is a load lock chamber.

28. The vacuum treatment method according to claim 27, wherein
for a first sample in which the loop processing has occurred, a total duration of time of the vacuum evacuation required for the measured internal pressure to reach the first reference value is measured, and the total duration of time is reflected in the first duration of time when targeting a sample of the same type as the first sample.

29. The vacuum treatment method according to claim 28, wherein
a third duration of time required for the internal pressure of the first vacuum chamber to reach a second reference value higher than the first reference value from a predetermined start time is measured, and whether the sample is of the same type as the first sample is determined based on the third duration of time.

30. The vacuum treatment method according to claim 29, wherein
for a second sample, the vacuum evacuation is stopped after having been performed by the vacuum pump for the first duration of time reflecting the total duration of time, and whether the internal pressure measured in a condition in which the vacuum evacuation is stopped reaches the first reference value is determined, and
it is determined that a third sample is of the same type as the second sample if the measured internal pressure in the second sample reaches the first reference value and the third durations of time are equivalent for the second sample and the third sample that is treated following the second sample.

31. The vacuum treatment method according to claim 26, wherein
the sample is conveyed from the first vacuum chamber to the second vacuum chamber, based on the amount of change or response characteristic of the measured internal pressure within the loop processing.

32. A vacuum treatment apparatus comprising:
a first vacuum chamber including a first gate valve to be opened and closed depending on conveyance of a sample to/from an apparatus;
a second vacuum chamber connected to the first vacuum chamber via a second gate valve;
a vacuum pump that vacuum-evacuates the first vacuum chamber via a vacuum valve; and
a computer system that controls conveyance of the sample from the first vacuum chamber to the second vacuum chamber through the second gate valve, wherein
the computer system controls to repeat an opening and closing operation of the vacuum valve or adjustment of the degree of opening while the sample stays in the first vacuum chamber and conveys the sample from the first vacuum chamber to the second vacuum chamber based on a result of comparison between a degree of vacuum or internal pressure of the first vacuum chamber within a control period and a predetermined threshold value, or the amount of change or response characteristic of the degree of vacuum or internal pressure of the first vacuum chamber within the control period.

33. The vacuum treatment apparatus according to claim 32, wherein
the first vacuum chamber is a load lock chamber.
